(19) United States
(12) Patent Application Publication
(10) Pub. No.: US 2026/0099112 A1
(43) Pub. Date: Apr. 9, 2026

(54) LIGHT EMITTING DEVICE

(71) Applicant: FUJIFILM Business Innovation Corp., Tokyo (JP)

(72) Inventor: Kei TAKEYAMA, Kanagawa (JP)

(73) Assignee: FUJIFILM Business Innovation Corp., Tokyo (JP)

(21) Appl. No.: 19/199,482

(22) Filed: May 6, 2025

(30) Foreign Application Priority Data
Oct. 7, 2024 (JP) 2024-175606

(51) Int. Cl. G03G 15/043; B41J 2/447; G03G 15/04; H01L 23/498; H01L 25/16

(52) U.S. Cl. CPC G03G 15/043; B41J 2/447; G03G 15/04036; H10W 70/65; H10W 90/00

(57) ABSTRACT

A light emitting device includes: multiple light-emitting-element arrays each including multiple light emitting elements; a first wire commonly connected to the multiple light-emitting-element arrays; a second wire connected to each of groups of multiple light-emitting-element arrays obtained by dividing the multiple light-emitting-element arrays; and a transfer unit that includes multiple transfer thyristors and that performs lighting control on the multiple light emitting elements included in each of the multiple light-emitting-element arrays via the first wire and the second wire, in which the transfer thyristors are larger in number than the light-emitting-element arrays, and the transfer thyristors that are adjacent to each other are connected to a single first light-emitting-element array included in the multiple light-emitting-element arrays.

### CROSS-REFERENCE TO RELATED APPLICATIONS

This application is based on and claims priority under 35 USC 119 from Japanese Patent Application No. 2024-175606 filed Oct. 7, 2024.

### BACKGROUND

### (i) Technical Field

The present disclosure relates to light emitting devices.

### (ii) Related Art

Japanese Patent No. 5316589 discloses an example of a known technique for radiating light onto different regions of an irradiation surface by using multiple segmented illumination light sources. Japanese Unexamined Patent Application Publication No. 2023-112927 discloses an example of a known configuration having multiple blocks that perform shifting operations and also having a shift signal line commonly provided for the multiple blocks and selecting a block that is to perform a shifting operation in accordance with a shift signal. In this configuration, the statuses of the blocks, such as a block #1 and a block #2, are inverted.

### SUMMARY

In order to control each of multiple light-emitting-element arrays, signal lines respectively connected to the multiple light-emitting-element arrays are necessary. If the number of light-emitting-element arrays is increased for independent control, multiple signal lines are necessary accordingly.

Aspects of non-limiting embodiments of the present disclosure relate to increasing the number of independently-controllable light-emitting-element arrays while suppressing an increase in the number of signal lines.

Aspects of certain non-limiting embodiments of the present disclosure address the above advantages and/or other advantages not described above. However, aspects of the non-limiting embodiments are not required to address the advantages described above, and aspects of the non-limiting embodiments of the present disclosure may not address advantages described above.

According to an aspect of the present disclosure, there is provided a light emitting device including: a plurality of light-emitting-element arrays each including a plurality of light emitting elements; a first wire commonly connected to the plurality of light-emitting-element arrays; a second wire connected to each of groups of multiple light-emitting-element arrays obtained by dividing the plurality of light-emitting-element arrays; and a transfer unit that includes a plurality of transfer thyristors and that performs lighting control on the plurality of light emitting elements included in each of the plurality of light-emitting-element arrays via the first wire and the second wire, wherein the transfer thyristors are larger in number than the light-emitting-element arrays, and the transfer thyristors that are adjacent to each other are connected to a single first light-emitting-element array included in the plurality of light-emitting-element arrays.

### BRIEF DESCRIPTION OF THE DRAWINGS

An exemplary embodiment of the present disclosure will be described in detail based on the following figures, wherein:

FIG. 1A illustrates an example of a combination of a light emitting unit and a transfer unit included in a light emitting device according to this exemplary embodiment, and FIG. 1B is a timing chart for explaining the operation of the light emitting unit and the transfer unit;

FIG. 2 illustrates an example where the light emitting device according to this exemplary embodiment has two chips each having a combination of the light emitting unit and the transfer unit;

FIG. 3A illustrates the configuration of a light emitting device in the related art, and FIG. 3B is a timing chart for explaining the operation of a light emitting unit and a transfer unit in the light emitting device in the related art;

FIG. 4 illustrates a specific example where the light emitting device according to this exemplary embodiment has two chips each having a combination of the light emitting unit and the transfer unit;

FIG. 5 illustrates a specific example where the light emitting device according to this exemplary embodiment has two chips each having a combination of the light emitting unit and the transfer unit;

FIG. 6 illustrates a specific example where the light emitting device according to this exemplary embodiment has four chips each having a combination of the light emitting unit and the transfer unit; and

FIG. 7 illustrates a specific example where the light emitting device according to this exemplary embodiment has eight chips each having a combination of the light emitting unit and the transfer unit.

### DETAILED DESCRIPTION

An exemplary embodiment of the present disclosure will be described below with reference to the appended drawings.

### Configuration of Light Emitting Device 1

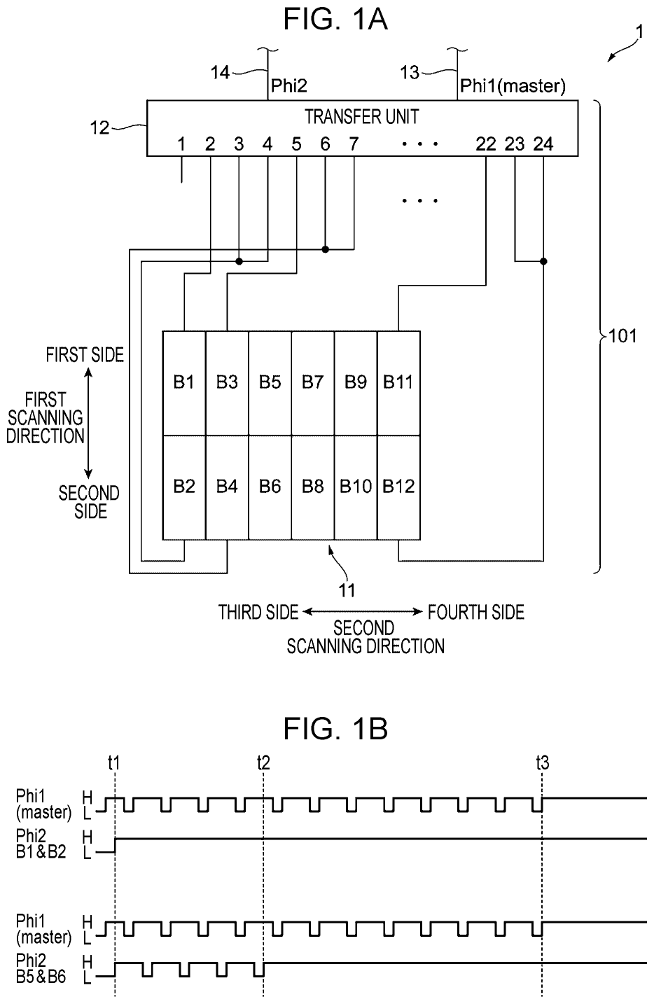

FIG. 1A illustrates an example of a combination of a light emitting unit 11 and a transfer unit 12 included in a light emitting device 1 according to this exemplary embodiment.

For example, the light emitting device 1 is used as an exposure device in a print head of a so-called tandem image forming apparatus. As shown in FIG. 1A, the light emitting device 1 has the light emitting unit 11, the transfer unit 12, a first wire 13, and a second wire 14.

### Light Emitting Unit 11

The light emitting unit 11 is constituted of blocks of multiple light-emitting-element arrays each including multiple light emitting elements. In FIG. 1A, rectangular blocks respectively indicating 12 light-emitting-element arrays each including multiple light emitting elements are shown, and are respectively indicated by being given numbers B1 to B12. The light emitting unit 11 has the blocks in a two-row-by-six-column arrangement toward the transfer unit 12, such that the odd-numbered blocks are disposed at a first side in a first scanning direction, whereas the even-numbered blocks are disposed at a second side in the first scanning direction.

In detail, the odd-numbered blocks B1, B3, B5, B7, B9, and B11 disposed at the first side in the first scanning direction are arranged in this order from a third side toward a fourth side in a second scanning direction. The even-numbered blocks B2, B4, B6, B8, B10, and B12 disposed at the second side in the first scanning direction are arranged in this order from the third side toward the fourth side in the second scanning direction.

In the example in FIG. 1A, the light emitting unit 11 is constituted of 12 blocks in the two-row-by-six-column arrangement toward the transfer unit 12, but is not limited to this arrangement. An alternative example is a two-row-by-n-column arrangement (n being an integer larger than or equal to 2), that is, two blocks arranged in a block-adjacent direction (first scanning direction) by n blocks arranged in a direction (second scanning direction) orthogonal to the block-adjacent direction. As another alternative, three or more blocks may be arranged in the block-adjacent direction (first scanning direction).

### Transfer Unit 12

The transfer unit 12 includes multiple transfer thyristors and performs lighting control on the multiple light emitting elements included in each of the multiple light-emitting-element arrays. The transfer unit 12 in FIG. 1A includes 24 transfer thyristors that are respectively indicated by being given a number “1” to a number “24”. In the example in FIG. 1A, the number “2” transfer thyristor is connected to the block B1 of the light emitting unit 11, and the number “3” transfer thyristor and the number “4” transfer thyristor are connected to the block B2 of the light emitting unit 11. The number “5” transfer thyristor is connected to the block B3 of the light emitting unit 11, and the number “6” transfer thyristor and the number “7” transfer thyristor are connected to the block B4 of the light emitting unit 11.

The transfer thyristors may be simultaneously set in an “ON” mode (lit mode) only when they are adjacent to each other. Therefore, in the example in FIG. 1A, for example, in order to cause the block B1 and the block B2 that are adjacent to each other in the light emitting unit 11 to emit light simultaneously, the following connection mode is set. Specifically, the number “2” transfer thyristor is connected to the block B1, and the number “3” transfer thyristor adjacent thereto and the number “4” transfer thyristor further adjacent thereto are connected to the same block B2. Moreover, for example, in order to cause the block B3 and the block B4 that are adjacent to each other to emit light simultaneously, the following connection mode is set. Specifically, the number “5” transfer thyristor is connected to the block B3, and the number “6” transfer thyristor adjacent thereto and the number “7” transfer thyristor further adjacent thereto are connected to the same block B4.

Accordingly, in the light emitting device 1, there is a case where one transfer thyristor is connected to one block of the light emitting unit 11 and a case where two adjacent transfer thyristors are connected to one block. Therefore, in the light emitting device 1, the number of transfer thyristors in the transfer unit 12 is greater than the number of light-emitting-element arrays (blocks) in the light emitting unit 11.

The first wire 13 (Phi1(master)) and the second wire 14 (Phi2) are connected to the transfer unit 12. The transfer unit 12 causes the blocks B1 to B12 of the light emitting unit 11 to emit light via the first wire 13 and the second wire 14. In combination with the light emitting unit 11 described above, the transfer unit 12 constitutes a single chip 101 that is independently distributable.

### First Wire 13

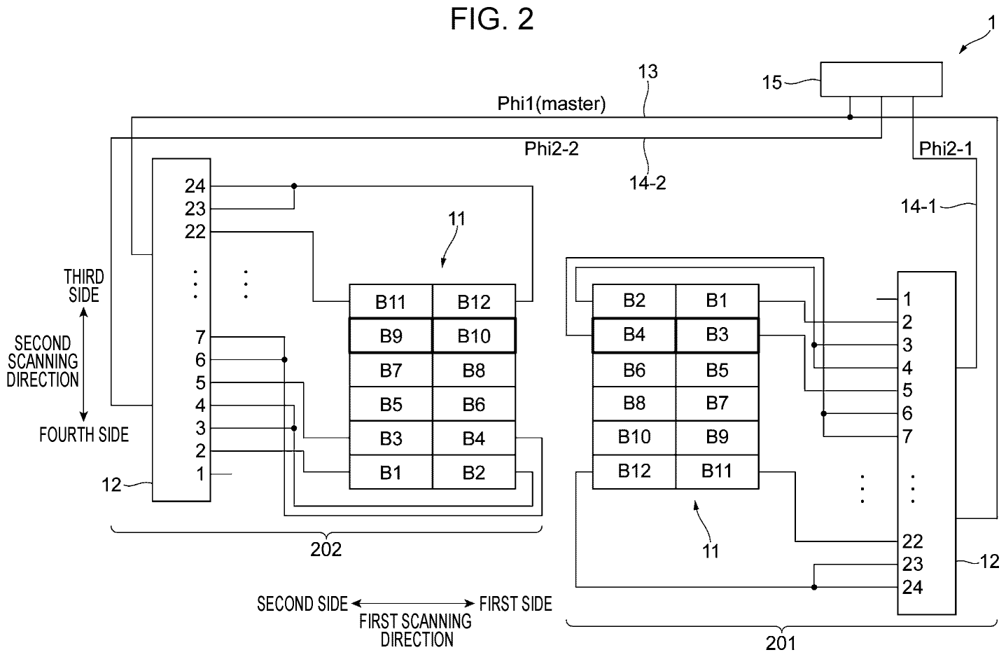

The first wire 13 is commonly connected to the multiple light-emitting-element arrays. In the example in FIG. 1A, the first wire 13 is commonly connected to the blocks B1 to B12 of the light emitting unit 11 in the chip 101 and to another plurality of light-emitting-element arrays. A specific example of “another plurality of light-emitting-element arrays” will be described later with reference to FIG. 2.

### Second Wire 14

The second wire 14 is connected to each of groups of multiple light-emitting-element arrays that are obtained by dividing the multiple light-emitting-element arrays. In the example in FIG. 1A, the second wire 14 is commonly connected to the blocks B1 to B12 constituting a group of multiple light-emitting-element arrays and to another group of multiple light-emitting-element arrays. A specific example of “another group of light-emitting-element arrays” will be described later with reference to FIG. 2.

FIG. 1B is a timing chart for explaining the operation of the light emitting unit 11 and the transfer unit 12. In the timing chart in FIG. 1B, “H” denotes a high level potential, whereas “L” denotes a low level potential. Time flows from left to right in the drawing. In the timing chart in FIG. 1B, Phi1(master) denotes the aforementioned first wire 13 in FIG. 1A, and Phi2 denotes the second wire 14 in FIG. 1A.

As shown in FIG. 1B, a signal (referred to as “first signal” hereinafter) transferred from the transfer unit 12 to the light emitting unit 11 via Phi1(master) repeatedly undergoes a transition from “L” to “H” and a transition from “H” to “L” at substantially fixed intervals, and maintains its state after transitioning from “L” to “H” at a timing t3. Of signals (referred to as “second signals” hereinafter) transferred from the transfer unit 12 to the light emitting unit 11 via Phi2, a second signal transferred to the blocks B1 and B2 of the light emitting unit 11 maintains its state after transitioning from “L” to “H” at a timing t1. Accordingly, the adjacent blocks B1 and B2 in the light emitting unit 11 are simultaneously lit. Of the second signals, a second signal transferred to the blocks B5 and B6 of the light emitting unit 11 maintains its state after transitioning from “L” to “H” at a timing t2. Accordingly, the blocks B5 and B6 adjacent to each other in the first scanning direction in the light emitting unit 11 are simultaneously lit.

The multiple light emitting elements constituting each block of the light emitting unit 11 are arranged long in a direction (first scanning direction) in which multiple blocks to be simultaneously lit are adjacent to each other. In detail, for example, in the example in FIG. 1A, the multiple light emitting elements constituting each of the block B1 and the block B2 that simultaneously emit light are arranged long in the direction (first scanning direction) in which the block B1 and the block B2 are adjacent to each other.

FIG. 2 illustrates an example where the light emitting device 1 according to this exemplary embodiment has two chips each having a combination of the light emitting unit 11 and the transfer unit 12.

Arranging multiple chips, each having a combination of the light emitting unit 11 and the transfer unit 12, in the first scanning direction enables a “line scan” where multiple light-emitting-element arrays are simultaneously lit linearly in the first scanning direction. FIG. 2 illustrates an example of the light emitting device 1 that realizes the line scan by having two chips 201 and 202 arranged opposing each other.

The configuration of the chip 201 shown in FIG. 2 is similar to the configuration of the aforementioned chip 101 shown in FIG. 1A. Specifically, the light emitting unit 11 of the chip 201 has the blocks in the two-row-by-six-column arrangement toward the transfer unit 12, such that the odd-numbered blocks are disposed at the first side in the first scanning direction, whereas the even-numbered blocks are disposed at the second side in the first scanning direction. In detail, the odd-numbered blocks B1, B3, B5, B7, B9, and B11 disposed at the first side in the first scanning direction are arranged in this order from the third side toward the fourth side in the second scanning direction. The even-numbered blocks B2, B4, B6, B8, B10, and B12 disposed at the second side in the first scanning direction are arranged in this order from the third side toward the fourth side in the second scanning direction.

The configuration of the chip 202 shown in FIG. 2 is also similar to the configuration of the aforementioned chip 101 shown in FIG. 1A. Specifically, the light emitting unit 11 of the chip 202 has the blocks in the two-row-by-six-column arrangement toward the transfer unit 12. However, because the chip 202 is disposed opposing the chip 201, the odd-numbered blocks are disposed at the second side in the first scanning direction, whereas the even-numbered blocks are disposed at the first side in the first scanning direction. In detail, the odd-numbered blocks B1, B3, B5, B7, B9, and B11 disposed at the second side in the first scanning direction are arranged in this order from the fourth side toward the third side in the second scanning direction. The even-numbered blocks B2, B4, B6, B8, B10, and B12 disposed at the first side in the first scanning direction are arranged in this order from the fourth side toward the third side in the second scanning direction.

The transfer unit 12 in each of the chips 201 and 202 includes 24 transfer thyristors that are respectively indicated by being given a number “1” to a number “24”. The connection mode between the light emitting unit 11 and the transfer unit 12 in each of the chips 201 and 202 is similar to the connection mode between the light emitting unit 11 and the transfer unit 12 in the chip 101 shown in FIG. 1A.

The transfer unit 12 in each of the chips 201 and 202 is connected to the first wire 13 (Phi1(master)). In the example in FIG. 2, the first wire 13 is commonly connected to the blocks B1 to B12 of the light emitting unit 11 in the chip 201 and to the blocks B1 to B12 of the light emitting unit 11 in the chip 202. The first wire 13 is connected to a controller 15 that controls the chips 201 and 202.

The transfer unit 12 in the chip 201 is connected to a second wire 14-1 (Phi2-1). In the example in FIG. 2, the second wire 14-1 is connected to the blocks B1 to B12, constituting a group of multiple light-emitting-element arrays, of the light emitting unit 11 in the chip 201. The second wire 14-1 is connected to the controller 15 that controls the chips 201 and 202. The transfer unit 12 in the chip 201 causes the blocks B1 to B12 of the light emitting unit 11 in the chip 201 to emit light via the first wire 13 and the second wire 14-1.

The transfer unit 12 in the chip 202 is connected to a second wire 14-2 (Phi2-2). In the example in FIG. 2, the second wire 14-2 is connected to the blocks B1 to B12, constituting a group of multiple light-emitting-element arrays, of the light emitting unit 11 in the chip 202. The second wire 14-2 is connected to the controller 15 that controls the chips 201 and 202. The transfer unit 12 in the chip 202 causes the blocks B1 to B12 of the light emitting unit 11 in the chip 202 to emit light via the first wire 13 and the second wire 14-2.

Accordingly, in the example in FIG. 2, the chip 201 and the chip 202 are disposed opposing each other. Therefore, for example, the blocks B3 and B4 adjacent to each other in the first scanning direction in the light emitting unit 11 of the chip 201 and the blocks B9 and B10 adjacent to each other in the first scanning direction in the light emitting unit 11 of the chip 202 may be simultaneously lit. As shown in FIG. 2, the blocks B3 and B4 in the chip 201 and the blocks B9 and B10 in the chip 202 form a single line in the first scanning direction, so that the aforementioned line scan is realized.

### COMPARATIVE EXAMPLE

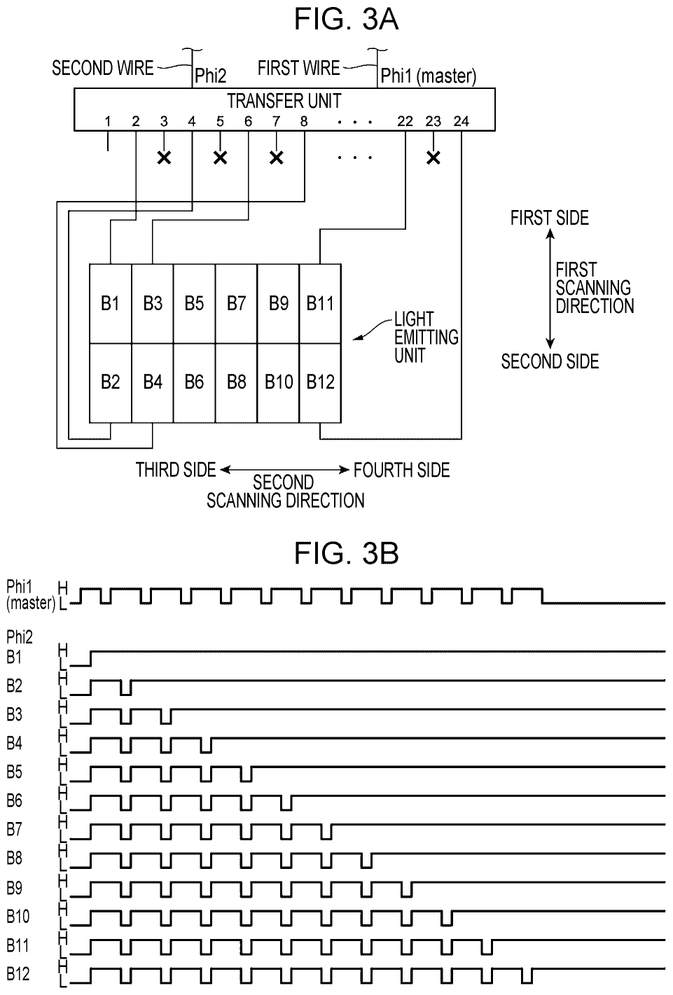

FIG. 3A illustrates the configuration of a light emitting device in the related art. FIG. 3B is a timing chart for explaining the operation of a light emitting unit and a transfer unit in the light emitting device in the related art. In the timing chart in FIG. 3B, “H” denotes a high level potential, whereas “L” denotes a low level potential. Time flows from left to right in the drawing. In the timing chart in FIG. 3B, Phi1(master) denotes a first wire, and Phi2 denotes a second wire.

Similar to the aforementioned light emitting device 1 according to this exemplary embodiment shown in FIGS. 1A to 2, the light emitting device in the related art has a light emitting unit and a transfer unit, and the combination of the light emitting unit and the transfer unit constitutes a single chip. The light emitting unit has blocks in a two-row-by-six-column arrangement toward the transfer unit, such that the odd-numbered blocks are disposed at the first side in the first scanning direction, whereas the even-numbered blocks are disposed at the second side in the first scanning direction. The transfer unit includes 24 transfer thyristors that are respectively indicated by being given a number “1” to a number “24”.

The light emitting device in the related art has a second wire connected to each chip, so that a block to be lit is designated for each chip. In detail, as shown in FIG. 3B, the blocks B1 to B12 are designated in this order for lighting by using a first signal transferred from the transfer unit to the light emitting unit via the common first wire and second signals transferred from the transfer unit to the light emitting unit via second wires respectively connected to the chips.

However, unlike the aforementioned light emitting device 1 according to this exemplary embodiment shown in FIGS. 1A to 2, the light emitting device in the related art allows only the even-numbered transfer thyristors of the 24 transfer thyristors of the transfer unit to share the first wire (Phi1(master)) connected to the light emitting unit. Therefore, it is difficult to simultaneously turn on two blocks adjacent to each other in the first scanning direction.

### First Modification

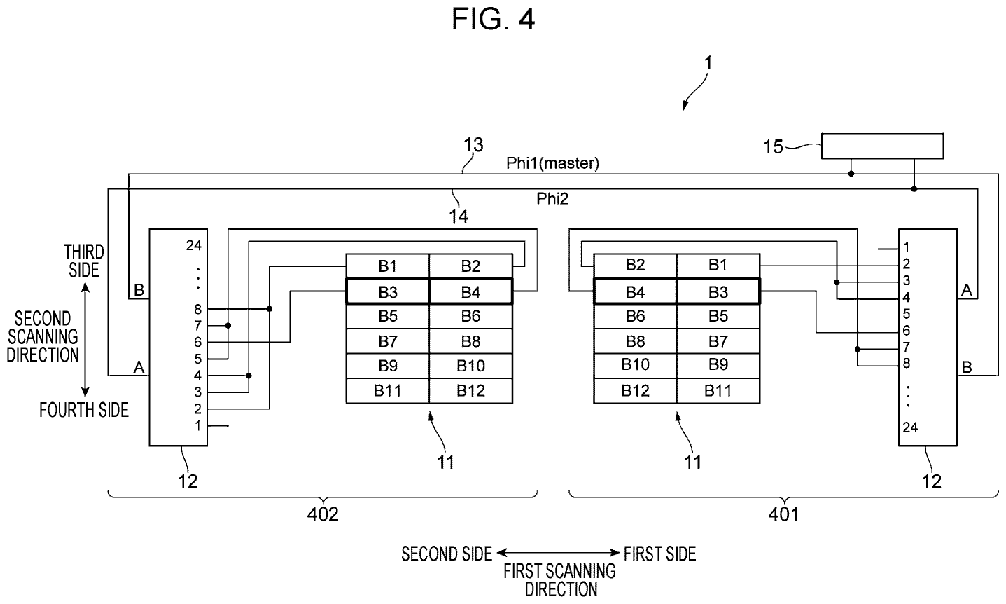

FIG. 4 illustrates a specific example where the light emitting device 1 according to this exemplary embodiment has two chips each having a combination of the light emitting unit 11 and the transfer unit 12.

As mentioned above, a line scan may be realized by arranging multiple chips, each having a combination of the light emitting unit 11 and the transfer unit 12, in the first scanning direction. FIG. 4 illustrates an example of the light emitting device 1 that realizes the line scan by having two chips 401 and 402 disposed substantially mirror-symmetrical to each other in the first scanning direction.

The configuration of the chip 401 shown in FIG. 4 is similar to the configuration of the aforementioned chip 101 shown in FIG. 1A. Specifically, the light emitting unit 11 of the chip 401 has the blocks in the two-row-by-six-column arrangement toward the transfer unit 12, such that the odd-numbered blocks are disposed at the first side in the first scanning direction, whereas the even-numbered blocks are disposed at the second side in the first scanning direction. In detail, the odd-numbered blocks B1, B3, B5, B7, B9, and B11 disposed at the first side in the first scanning direction are arranged in this order from the third side toward the fourth side in the second scanning direction. The even-numbered blocks B2, B4, B6, B8, B10, and B12 disposed at the second side in the first scanning direction are arranged in this order from the third side toward the fourth side in the second scanning direction.

The configuration of the chip 402 shown in FIG. 4 is basically similar to the configuration of the aforementioned chip 101 shown in FIG. 1A. Specifically, the light emitting unit 11 of the chip 402 has the blocks in the two-row-by-six-column arrangement toward the transfer unit 12. However, because the chip 402 is disposed substantially mirror-symmetrical to the chip 401, the odd-numbered blocks are disposed at the second side in the first scanning direction, whereas the even-numbered blocks are disposed at the first side in the first scanning direction. In detail, the odd-numbered blocks B1, B3, B5, B7, B9, and B11 disposed at the second side in the first scanning direction are arranged in this order from the third side toward the fourth side in the second scanning direction. The even-numbered blocks B2, B4, B6, B8, B10, and B12 disposed at the first side in the first scanning direction are arranged in this order from the third side toward the fourth side in the second scanning direction.

The transfer unit 12 in each of the chips 401 and 402 includes 24 transfer thyristors that are respectively indicated by being given a number “1” to a number “24”. Since the connection mode between the light emitting unit 11 and the transfer unit 12 in each of the chips 401 and 402 is basically similar to the connection mode between the light emitting unit 11 and the transfer unit 12 in the chip 101 shown in FIG. 1A, a part of the drawing has been omitted.

The transfer unit 12 in each of the chips 401 and 402 is connected to the first wire 13 (Phi1(master)). In the example in FIG. 4, the first wire 13 is commonly connected to the blocks B1 to B12 of the light emitting unit 11 in the chip 401 and to the blocks B1 to B12 of the light emitting unit 11 in the chip 402. The first wire 13 is connected to the blocks B1 to B12 of the light emitting unit 11 in the chip 401 via a terminal B of the transfer unit 12 therein, and is connected to the blocks B1 to B12 of the light emitting unit 11 in the chip 402 via a terminal B of the transfer unit 12 therein. The first wire 13 is connected to the controller 15 that controls the chips 401 and 402.

The transfer unit 12 in each of the chips 401 and 402 is connected to the second wire 14 (Phi2). In the example in FIG. 4, the second wire 14 is commonly connected to the blocks B1 to B12, constituting a group of multiple light-emitting-element arrays, of the light emitting unit 11 in the chip 401 and to the blocks B1 to B12, constituting a group of multiple light-emitting-element arrays, of the light emitting unit 11 in the chip 402. The second wire 14 is connected to the blocks B1 to B12 of the light emitting unit 11 in the chip 401 via a terminal A of the transfer unit 12 therein, and is connected to the blocks B1 to B12 of the light emitting unit 11 in the chip 402 via a terminal A of the transfer unit 12 therein. The second wire 14 is connected to the controller 15 that controls the chips 401 and 402.

The transfer unit 12 in the chip 401 causes the blocks B1 to B12 of the light emitting unit 11 in the chip 401 to emit light via the first wire 13 and the second wire 14. The transfer unit 12 in the chip 402 causes the blocks B1 to B12 of the light emitting unit 11 in the chip 402 to emit light via the first wire 13 and the second wire 14. Specifically, with the two chips 401 and 402 being disposed substantially mirror-symmetrical to each other in the first scanning direction, the second wire 14 is also shared in addition to the first wire 13.

Accordingly, in the example in FIG. 4, the chip 401 and the chip 402 are disposed substantially mirror-symmetrical to each other in the first scanning direction. Therefore, for example, the blocks B3 and B4 adjacent to each other in the first scanning direction in the light emitting unit 11 of the chip 401 and the blocks B3 and B4 adjacent to each other in the first scanning direction in the light emitting unit 11 of the chip 402 may be simultaneously lit. As shown in FIG. 4, the blocks B3 and B4 in the chip 401 and the blocks B3 and B4 in the chip 402 form a single line in the first scanning direction, so that the aforementioned line scan is realized.

### Second Modification

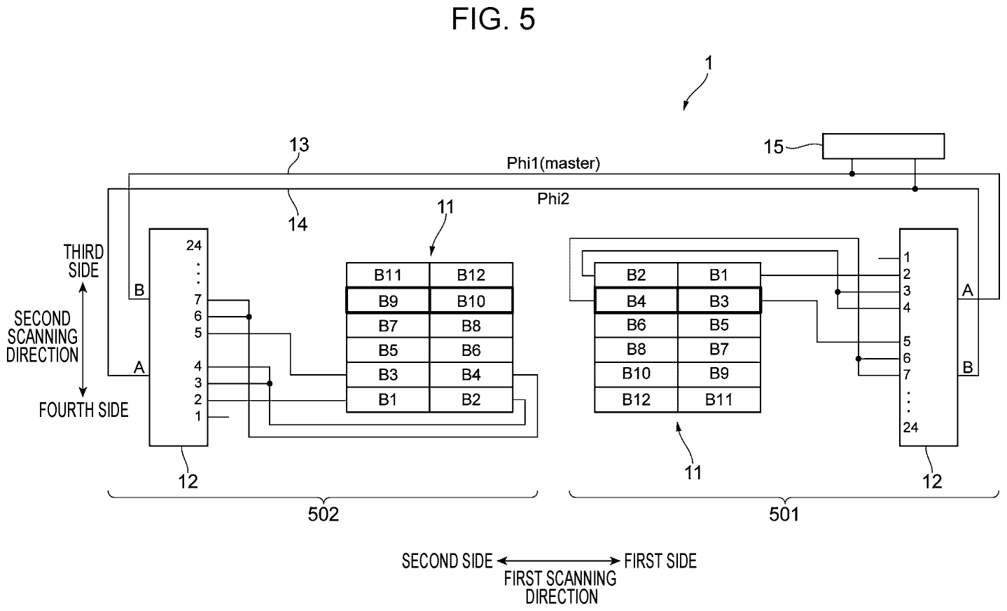

FIG. 5 illustrates a specific example where the light emitting device 1 according to this exemplary embodiment has two chips each having a combination of the light emitting unit 11 and the transfer unit 12.

As mentioned above, a line scan may be realized by arranging multiple chips, each having a combination of the light emitting unit 11 and the transfer unit 12, in the first scanning direction. FIG. 5 illustrates an example of the light emitting device 1 that realizes the line scan by having two chips 501 and 502 disposed substantially point-symmetrical to each other in the first scanning direction.

The configuration of the chip 501 shown in FIG. 5 is similar to the configuration of the aforementioned chip 101 shown in FIG. 1A. Specifically, the light emitting unit 11 of the chip 501 has the blocks in the two-row-by-six-column arrangement toward the transfer unit 12, such that the odd-numbered blocks are disposed at the first side in the first scanning direction, whereas the even-numbered blocks are disposed at the second side in the first scanning direction. In detail, the odd-numbered blocks B1, B3, B5, B7, B9, and B11 disposed at the first side in the first scanning direction are arranged in this order from the third side toward the fourth side in the second scanning direction. The even-numbered blocks B2, B4, B6, B8, B10, and B12 disposed at the second side in the first scanning direction are arranged in this order from the third side toward the fourth side in the second scanning direction.

During a shifting operation, the chip 502 shown in FIG. 5 is configured to reverse the lighting order between when starting from the first wire 13 (Phi1(master)) and when starting from the second wire 14 (Phi2). The remaining configuration is basically similar to the configuration of the aforementioned chip 101 shown in FIG. 1A. A known configuration has multiple blocks that perform shifting operations, and also has a shift signal line commonly provided for the multiple blocks and selecting a block that is to perform a shifting operation in accordance with a shift signal. In such a configuration, the statuses of the blocks, such as the first block and the second block, are inverted. In contrast, in this exemplary embodiment, the circuit structure is applied to each chip, and the blocks are designated in a state where the chip to which a signal is transferred in the forward direction and the chip to which a signal is transferred in the reverse direction oppose each other in a point-symmetrical fashion.

The light emitting unit 11 of the chip 502 has the blocks in the two-row-by-six-column arrangement toward the transfer unit 12. However, because the chip 502 is disposed substantially point-symmetrical to the chip 501, the odd-numbered blocks are disposed at the second side in the first scanning direction, whereas the even-numbered blocks are disposed at the first side in the first scanning direction. In detail, the odd-numbered blocks B1, B3, B5, B7, B9, and B11 disposed at the second side in the first scanning direction are arranged in this order from the fourth side toward the third side in the second scanning direction. The even-numbered blocks B2, B4, B6, B8, B10, and B12 disposed at the first side in the first scanning direction are arranged in this order from the fourth side toward the third side in the second scanning direction.

The transfer unit 12 in each of the chips 501 and 502 includes 24 transfer thyristors that are respectively indicated by being given a number “1” to a number “24”. Since the connection mode between the light emitting unit 11 and the transfer unit 12 in each of the chips 501 and 502 is basically similar to the connection mode between the light emitting unit 11 and the transfer unit 12 in the chip 101 shown in FIG. 1A, a part of the drawing has been omitted.

The transfer unit 12 in each of the chips 501 and 502 is connected to the first wire 13 (Phi1(master)). The first wire 13 is connected to the controller 15 that controls the chips 501 and 502. In the example in FIG. 5, the first wire 13 is commonly connected to the blocks B1 to B12 of the light emitting unit 11 in the chip 501 and to the blocks B1 to B12 of the light emitting unit 11 in the chip 502. The first wire 13 is connected to the blocks B1 to B12 of the light emitting unit 11 in the chip 501 via the terminal A of the transfer unit 12 therein, and is connected to the blocks B1 to B12 of the light emitting unit 11 in the chip 502 via the terminal B of the transfer unit 12 therein. Specifically, the terminals for connecting the first wire 13 to the transfer units 12 are inverted between the chip 501 and the chip 502 (i.e., A and B are inverted). With regard to the chips 501 and 502 in the example in FIG. 5, the transfer is inverted between when a signal starts from the first wire 13 (Phi1(master)) and when a signal starts from the second wire 14 (Phi2). As a result, the terminals A and the terminals B are inverted between the chip 501 and the chip 502, so that the blocks arranged in the point-symmetrical chips are simultaneously lit.

In the example in FIG. 5, four blocks included in the chip 501 and the chip 502 and arranged in a single line in the first scanning direction are designated and are simultaneously lit. For example, a total of four blocks, namely, the blocks B1 and B2 adjacent to each other in the first scanning direction in the light emitting unit 11 of the chip 501 and the blocks B11 and B12 adjacent to each other in the first scanning direction in the light emitting unit 11 of the chip 502, are designated and are simultaneously lit. Moreover, a total of four blocks, namely, the blocks B3 and B4 adjacent to each other in the first scanning direction in the light emitting unit 11 of the chip 501 and the blocks B9 and B10 adjacent to each other in the first scanning direction in the light emitting unit 11 of the chip 502, are designated and are simultaneously lit.

Furthermore, a combination of the blocks B5 and B6 in the chip 501 and the blocks B7 and B8 in the chip 502 and a combination of the blocks B7 and B8 in the chip 501 and the blocks B5 and B6 in the chip 502 are similarly designated and are simultaneously lit. Moreover, a combination of the blocks B9 and B10 in the chip 501 and the blocks B3 and B4 in the chip 502 and a combination of the blocks B11 and B12 in the chip 501 and the blocks B1 and B2 in the chip 502 are similarly designated and are simultaneously lit.

The transfer unit 12 in each of the chip 501 and the chip 502 is connected to the second wire 14 (Phi2). In the example in FIG. 5, the second wire 14 is commonly connected to the blocks B1 to B12, constituting a group of multiple light-emitting-element arrays, of the light emitting unit 11 in the chip 501 and to the blocks B1 to B12, constituting a group of multiple light-emitting-element arrays, of the light emitting unit 11 in the chip 502. The second wire 14 is connected to the blocks B1 to B12 of the light emitting unit 11 in the chip 501 via the terminal B of the transfer unit 12 therein, and is connected to the blocks B1 to B12 of the light emitting unit 11 in the chip 502 via the terminal A of the transfer unit 12 therein. Specifically, the terminals for connecting the second wire 14 to the transfer units 12 are inverted between the chip 501 and the chip 502 (i.e., A and B are inverted). The second wire 14 is connected to the controller 15 that controls the chips 501 and 502.

The transfer unit 12 in the chip 501 causes the blocks B1 to B12 of the light emitting unit 11 in the chip 501 to emit light via the first wire 13 and the second wire 14. The transfer unit 12 in the chip 502 causes the blocks B1 to B12 of the light emitting unit 11 in the chip 502 to emit light via the first wire 13 and the second wire 14. Specifically, with the two chips 501 and 502 being disposed substantially point-symmetrical to each other in the first scanning direction, the second wire 14 is also shared in addition to the first wire 13.

Accordingly, in the example in FIG. 5, the chip 501 and chip 502 are disposed substantially point-symmetrical to each other in the first scanning direction. Therefore, for example, the blocks B3 and B4 adjacent to each other in the first scanning direction in the light emitting unit 11 of the chip 501 and the blocks B9 and B10 adjacent to each other in the first scanning direction in the light emitting unit 11 of the chip 502 may be simultaneously lit. As shown in FIG. 5, the blocks B3 and B4 in the chip 501 and the blocks B9 and B10 in the chip 502 form a single line in the first scanning direction, so that the aforementioned line scan is realized.

### Third Modification

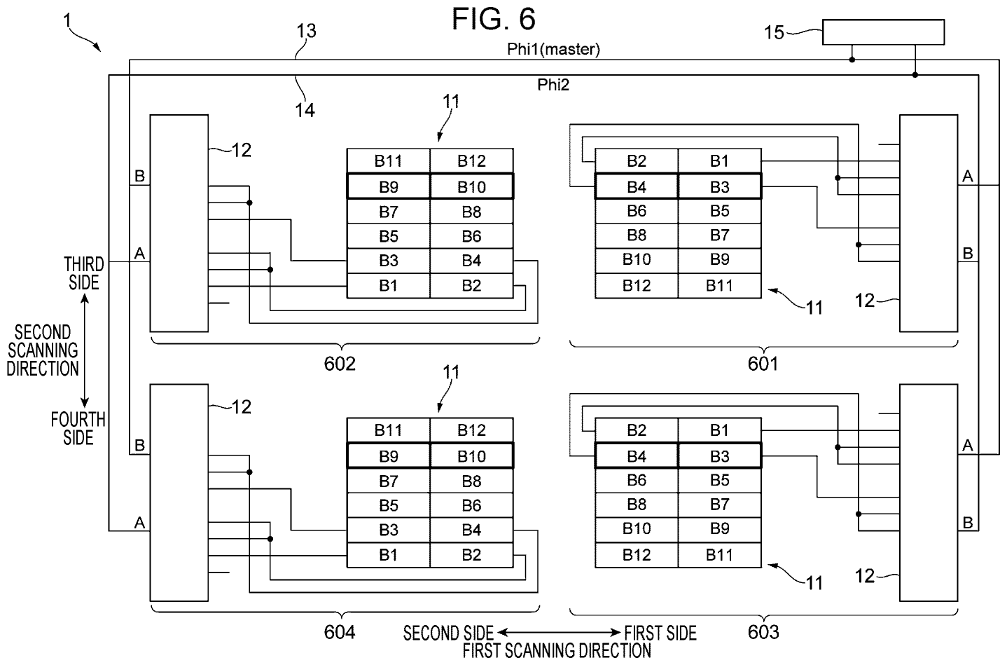

FIG. 6 illustrates a specific example where the light emitting device 1 according to this exemplary embodiment has four chips each having a combination of the light emitting unit 11 and the transfer unit 12.

As mentioned above, a line scan may be realized by arranging multiple chips, each having a combination of the light emitting unit 11 and the transfer unit 12, in the first scanning direction. FIG. 6 illustrates an example of the light emitting device 1 that realizes a line scan by having four chips 601 to 604 arranged such that the chips 601 and 602 and the chips 603 and 604 are disposed substantially point-symmetrical to each other in the first scanning direction.

The configuration of each of the chips 601 and 602 shown in FIG. 6 is similar to the configuration of each of the aforementioned chips 501 and 502 shown in FIG. 5. Likewise, the configuration of each of the chips 603 and 604 shown in FIG. 6 is similar to the configuration of each of the aforementioned chips 501 and 502 shown in FIG. 5. Therefore, a part of the drawing has been omitted.

The transfer unit 12 in each of the chips 601 to 604 is connected to the first wire 13 (Phi1(master)). In the example in FIG. 6, the first wire 13 is commonly connected to the blocks B1 to B12 of the light emitting unit 11 in each of the chips 601 to 604. The first wire 13 is connected to the blocks B1 to B12 of the light emitting unit 11 in the chip 601 via the terminal A of the transfer unit 12 therein, and is connected to the blocks B1 to B12 of the light emitting unit 11 in the chip 602 via the terminal B of the transfer unit 12 therein.

The first wire 13 is connected to the blocks B1 to B12 of the light emitting unit 11 in the chip 603 via the terminal A of the transfer unit 12 therein, and is connected to the blocks B1 to B12 of the light emitting unit 11 in the chip 604 via the terminal B of the transfer unit 12 therein. The first wire 13 is connected to the controller 15 that controls the chips 601 to 604.

The transfer unit 12 in each of the chips 601 to 604 is connected to the second wire 14 (Phi2). In the example in FIG. 6, the second wire 14 is commonly connected to the blocks B1 to B12, constituting a group of multiple light-emitting-element arrays, of the light emitting unit 11 in each of the chips 601 to 604. The second wire 14 is connected to the blocks B1 to B12 of the light emitting unit 11 in the chip 601 via the terminal B of the transfer unit 12 therein, and is connected to the blocks B1 to B12 of the light emitting unit 11 in the chip 602 via the terminal A of the transfer unit 12 therein.

The second wire 14 is connected to the blocks B1 to B12 of the light emitting unit 11 in the chip 603 via the terminal B of the transfer unit 12 therein, and is connected to the blocks B1 to B12 of the light emitting unit 11 in the chip 604 via the terminal A of the transfer unit 12 therein. The second wire 14 is connected to the controller 15 that controls the chips 601 to 604.

The transfer unit 12 in each of the chips 601 to 604 causes the blocks B1 to B12 of the light emitting unit 11 in each of the chips 601 to 604 to emit light via the first wire 13 and the second wire 14. Specifically, the four chips 601 to 604 are arranged such that the chips 601 and 602 and the chips 603 and 604 are disposed substantially point-symmetrical to each other in the first scanning direction, so that the second wire 14 is also shared in addition to the first wire 13.

Accordingly, in the example in FIG. 6, the chips 601 and 602 and the chips 603 and 604 are disposed substantially point-symmetrical to each other in the first scanning direction. Therefore, for example, the blocks B3 and B4 in the chip 601, the blocks B9 and B10 in the chip 602, the blocks B3 and B4 in the chip 603, and the blocks B9 and B10 in the chip 604 may be simultaneously lit. As shown in FIG. 6, the blocks B3 and B4 in the chip 601 and the blocks B9 and B10 in the chip 602 form a single line in the first scanning direction. Moreover, the blocks B3 and B4 in the chip 603 and the blocks B9 and B10 in the chip 604 form a single line in the first scanning direction. Therefore, the light emitting device 1 in FIG. 6 realizes the aforementioned line scan.

If the light emitting units 11 in the respective chips 601 and 602 are to be lit and the light emitting units 11 in the respective chips 603 and 604 are not to be lit, the controller 15 performs control accordingly. If the light emitting units 11 in the respective chips 603 and 604 are to be lit and the light emitting units 11 in the respective chips 601 and 602 are not to be lit, the controller 15 performs control accordingly.

### Fourth Modification

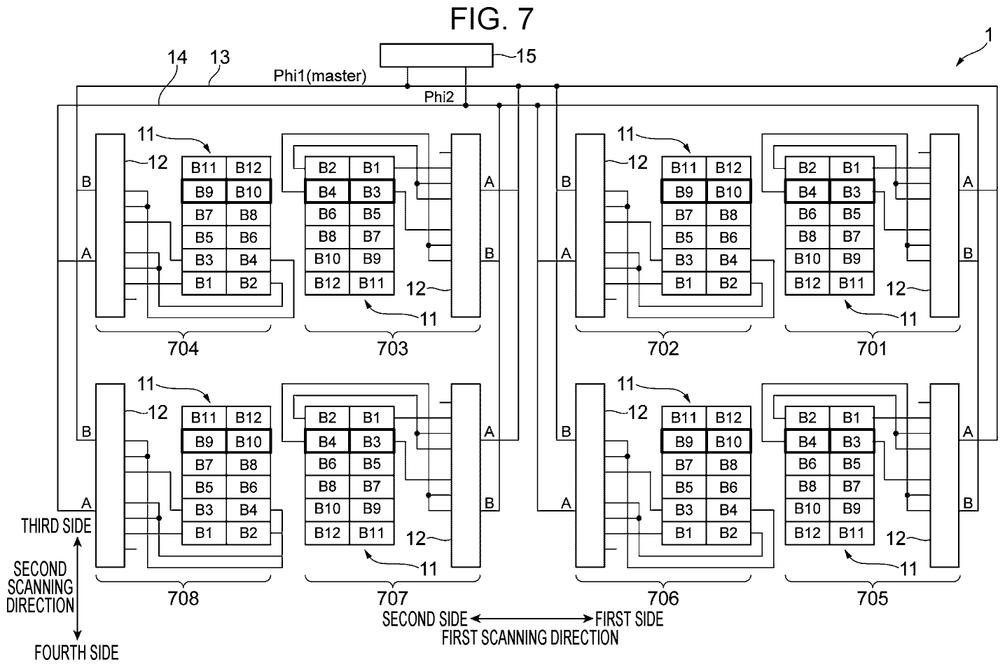

FIG. 7 illustrates a specific example where the light emitting device 1 according to this exemplary embodiment has eight chips each having a combination of the light emitting unit 11 and the transfer unit 12.

As mentioned above, a line scan may be realized by arranging multiple chips, each having a combination of the light emitting unit 11 and the transfer unit 12, in the first scanning direction. FIG. 7 illustrates an example of the light emitting device 1 that realizes a line scan by having eight chips 701 to 708 arranged such that four sets of opposing chips are disposed substantially point-symmetrical to one another in the first scanning direction.

As shown in FIG. 7, the configuration of each of the opposing chips 701 and 702, the opposing chips 703 and 704, the opposing chips 705 and 706, and the opposing chips 707 and 708 is similar to the configuration of each of the aforementioned chips 501 and 502 shown in FIG. 5. Therefore, a part of the drawing has been omitted.

The transfer unit 12 in each of the chips 701 to 708 is connected to the first wire 13 (Phi1(master)). In the example in FIG. 7, the first wire 13 is commonly connected to the blocks B1 to B12 of the light emitting unit 11 in each of the chips 701 to 708. The first wire 13 is connected to the blocks B1 to B12 of the light emitting unit 11 in the chip 701 via the terminal A of the transfer unit 12 therein, and is connected to the blocks B1 to B12 of the light emitting unit 11 in the chip 702 via the terminal B of the transfer unit 12 therein.

The first wire 13 is connected to the blocks B1 to B12 of the light emitting unit 11 in the chip 703 via the terminal A of the transfer unit 12 therein, and is connected to the blocks B1 to B12 of the light emitting unit 11 in the chip 704 via the terminal B of the transfer unit 12 therein. The first wire 13 is connected to the blocks B1 to B12 of the light emitting unit 11 in the chip 705 via the terminal A of the transfer unit 12 therein, and is connected to the blocks B1 to B12 of the light emitting unit 11 in the chip 706 via the terminal B of the transfer unit 12 therein.

The first wire 13 is connected to the blocks B1 to B12 of the light emitting unit 11 in the chip 707 via the terminal A of the transfer unit 12 therein, and is connected to the blocks B1 to B12 of the light emitting unit 11 in the chip 708 via the terminal B of the transfer unit 12 therein. The first wire 13 is connected to the controller 15 that controls the chips 701 to 708.

The transfer unit 12 in each of the chips 701 to 708 is connected to the second wire 14 (Phi2). In the example in FIG. 7, the second wire 14 is commonly connected to the blocks B1 to B12, constituting a group of multiple light-emitting-element arrays, of the light emitting unit 11 in each of the chips 701 to 708. The second wire 14 is connected to the blocks B1 to B12 of the light emitting unit 11 in the chip 701 via the terminal B of the transfer unit 12 therein, and is connected to the blocks B1 to B12 of the light emitting unit 11 in the chip 702 via the terminal A of the transfer unit 12 therein.

The second wire 14 is connected to the blocks B1 to B12 of the light emitting unit 11 in the chip 703 via the terminal B of the transfer unit 12 therein, and is connected to the blocks B1 to B12 of the light emitting unit 11 in the chip 704 via the terminal A of the transfer unit 12 therein. The second wire 14 is connected to the blocks B1 to B12 of the light emitting unit 11 in the chip 705 via the terminal B of the transfer unit 12 therein, and is connected to the blocks B1 to B12 of the light emitting unit 11 in the chip 706 via the terminal A of the transfer unit 12 therein.

The second wire 14 is connected to the blocks B1 to B12 of the light emitting unit 11 in the chip 707 via the terminal B of the transfer unit 12 therein, and is connected to the blocks B1 to B12 of the light emitting unit 11 in the chip 708 via the terminal A of the transfer unit 12 therein. The second wire 14 is connected to the controller 15 that controls the chips 701 to 708.

The transfer unit 12 in each of the chips 701 to 708 causes the blocks B1 to B12 of the light emitting unit 11 in each of the chips 701 to 708 to emit light via the first wire 13 and the second wire 14. Specifically, the eight chips 701 to 708 are arranged such that the four sets of opposing chips are disposed substantially point-symmetrical to one another in the first scanning direction, so that the second wire 14 is also shared in addition to the first wire 13.

Accordingly, in the example in FIG. 7, the four sets of opposing chips are disposed substantially point-symmetrical to one another in the first scanning direction. Therefore, for example, the blocks B3 and B4 in each of the chips 701, 703, 705, and 707 and the blocks B9 and B10 in each of the chips 702, 704, 706, and 708 may be simultaneously lit.

As shown in FIG. 7, the blocks B3 and B4 in each of the chips 701 and 703 and the blocks B9 and B10 in each of the chips 702 and 704 form a single line in the first scanning direction. Moreover, the blocks B3 and B4 in each of the chips 705 and 707 and the blocks B9 and B10 in each of the chips 706 and 708 form a single line in the first scanning direction. Therefore, the light emitting device 1 in FIG. 7 realizes the aforementioned line scan.

If the light emitting units 11 in the respective chips 701 to 704 are to be lit and the light emitting units 11 in the respective chips 705 to 708 are not to be lit, the controller 15 performs control accordingly. If the light emitting units 11 in the respective chips 705 to 708 are to be lit and the light emitting units 11 in the respective chips 701 to 704 are not to be lit, the controller 15 performs control accordingly.

### Other Exemplary Embodiments

Although the exemplary embodiment has been described above, the above exemplary embodiment of the present disclosure is not limited thereto. The advantages of the exemplary embodiment of the present disclosure are also not limited to those described in the above exemplary embodiment. For example, the configuration of the light emitting device 1 shown in each of FIGS. 1A, 2, and 4 to 7 is exemplary and is not particularly limited.

Although the above exemplary embodiment has been described with reference to a specific example where two opposing chips are substantially mirror-symmetrical or substantially point-symmetrical, the configuration is not limited thereto. For example, the two opposing chips may be substantially line-symmetrical.

The foregoing description of the exemplary embodiments of the present disclosure has been provided for the purposes of illustration and description. It is not intended to be exhaustive or to limit the disclosure to the precise forms disclosed. Obviously, many modifications and variations will be apparent to practitioners skilled in the art. The embodiments were chosen and described in order to best explain the principles of the disclosure and its practical applications, thereby enabling others skilled in the art to understand the disclosure for various embodiments and with the various modifications as are suited to the particular use contemplated. It is intended that the scope of the disclosure be defined by the following claims and their equivalents.

### APPENDIX

(((1))) A light emitting device comprising:
a plurality of light-emitting-element arrays each including a plurality of light emitting elements;
a first wire commonly connected to the plurality of light-emitting-element arrays;
a second wire connected to each of groups of multiple light-emitting-element arrays obtained by dividing the plurality of light-emitting-element arrays; and
a transfer unit that includes a plurality of transfer thyristors and that performs lighting control on the plurality of light emitting elements included in each of the plurality of light-emitting-element arrays via the first wire and the second wire,
wherein the transfer thyristors are larger in number than the light-emitting-element arrays, and the transfer thyristors that are adjacent to each other are connected to a single first light-emitting-element array included in the plurality of light-emitting-element arrays.

(((2))) The light emitting device according to (((1))),
wherein a second light-emitting-element array included in the plurality of light-emitting-element arrays is adjacent to the first light-emitting-element array and is lit simultaneously with the first light-emitting-element array, the second light-emitting-element array being connected to the transfer thyristor disposed further adjacent to the transfer thyristor connected to the first light-emitting-element array.

(((3))) The light emitting device according to (((1))) or (((2))),
wherein the plurality of light emitting elements included in the first light-emitting-element array are arranged long in a direction in which the light-emitting-element arrays to be simultaneously lit are adjacent to each other.

(((4))) The light emitting device according to (((3))),
wherein the plurality of light-emitting-element arrays include two light-emitting-element arrays arranged in the direction of adjacency and n light-emitting-element arrays arranged in a direction orthogonal to the direction of adjacency, n being an integer larger than or equal to 2.

(((5))) The light emitting device according to (((2))) or (((3))),
wherein two chips are disposed opposing each other, each chip being constituted by a combination of the transfer unit and the plurality of light-emitting-element arrays, and
wherein the light-emitting-element arrays in the two chips are simultaneously lit in a direction in which the light-emitting-element arrays are adjacent to each other.

(((6))) The light emitting device according to (((5))),
wherein the two chips share a line connected to the first wire.

(((7))) The light emitting device according to (((6))),
wherein the two chips disposed opposing each other have substantially line-symmetrical configurations.

(((8))) The light emitting device according to (((6))),
wherein the two chips have substantially mirror-symmetrical connections with respect to the first wire and the second wire that connect the light-emitting-element arrays and the transfer unit to each other, and share a line connected to the second wire.

(((9))) The light emitting device according to (((6))),
wherein the two chips disposed opposing each other have substantially point-symmetrical configurations.

What is claimed is:

1. A light emitting device comprising:
a plurality of light-emitting-element arrays each including a plurality of light emitting elements;
a first wire commonly connected to the plurality of light-emitting-element arrays;
a second wire connected to each of groups of multiple light-emitting-element arrays obtained by dividing the plurality of light-emitting-element arrays; and
a transfer unit that includes a plurality of transfer thyristors and that performs lighting control on the plurality of light emitting elements included in each of the plurality of light-emitting-element arrays via the first wire and the second wire,
wherein the transfer thyristors are larger in number than the light-emitting-element arrays, and the transfer thyristors that are adjacent to each other are connected to a single first light-emitting-element array included in the plurality of light-emitting-element arrays.

2. The light emitting device according to claim 1,
wherein a second light-emitting-element array included in the plurality of light-emitting-element arrays is adjacent to the first light-emitting-element array and is lit simultaneously with the first light-emitting-element array, the second light-emitting-element array being connected to the transfer thyristor disposed further adjacent to the transfer thyristor connected to the first light-emitting-element array.

3. The light emitting device according to claim 2,
wherein the plurality of light emitting elements included in the first light-emitting-element array are arranged long in a direction in which the light-emitting-element arrays to be simultaneously lit are adjacent to each other.

4. The light emitting device according to claim 3,
wherein the plurality of light-emitting-element arrays include two light-emitting-element arrays arranged in the direction of adjacency and n light-emitting-element arrays arranged in a direction orthogonal to the direction of adjacency, n being an integer larger than or equal to 2.

5. The light emitting device according to claim 2,
wherein two chips are disposed opposing each other, each chip being constituted by a combination of the transfer unit and the plurality of light-emitting-element arrays, and
wherein the light-emitting-element arrays in the two chips are simultaneously lit in a direction in which the light-emitting-element arrays are adjacent to each other.

6. The light emitting device according to claim 5,
wherein the two chips share a line connected to the first wire.

7. The light emitting device according to claim 6,
wherein the two chips disposed opposing each other have substantially line-symmetrical configurations.

8. The light emitting device according to claim 6,
wherein the two chips have substantially mirror-symmetrical connections with respect to the first wire and the second wire that connect the light-emitting-element arrays and the transfer unit to each other, and share a line connected to the second wire.

9. The light emitting device according to claim 6,
wherein the two chips disposed opposing each other have substantially point-symmetrical configurations.
